(19) United States
(12) Patent Application Publication
(10) Pub. No.: US 2007/0032059 A1
(43) Pub. Date: Feb. 8, 2007

(54) Method of manufacturing a semiconductor structure having a wafer through-contact and a corresponding semiconductor structure

(76) Inventors: Harry Hedler, Germering (DE); Roland Irsigler, Munchen (DE)

Correspondence Address: JENKINS, WILSON, TAYLOR & HUNT, P. A., 3100 TOWER BLVD, SUITE 1200, DURHAM, NC, 27707, US

(21) Appl. No.: 11/195,462

(22) Filed: Aug. 2, 2005

(51) Int. Cl. H01L 21/44

(52) U.S. Cl. 438/597

(57) ABSTRACT

A method of manufacturing a semiconductor structure having a wafer through-contact and a corresponding semiconductor structure

This invention provides a method of manufacturing a semiconductor structure having a wafer through-contact and a corresponding semiconductor structure. The method comprises the steps of: providing a semiconductor wafer (1) having a bulk region (1a) and an active region (1b); forming a plurality of contact trenches (5a-5f) in said semiconductor wafer (1) which extend from an upper surface (O) of said active region (1b) into said bulk region (1a); forming a first dielectric isolation layer (8) on the sidewalls and the bottoms of said contact trenches (5a-5f); providing a first conductive filling (10) in said plurality of contact trenches (5a-5f); forming an aligned via (V) in said semiconductor wafer (1) which extends from a backside (B) of said bulk region (1a) into said plurality of contact trenches (5a-5f) and exposes the conductive filling (10) of said plurality of contact trenches (5a-5f); providing a second dielectric isolation layer (15) on the sidewall of said via (V); and providing a second conductive filling (20) in said via (V) which contacts the exposed conductive filling (10) of said plurality of contact trenches (5a-5f) thus forming said wafer through-contact.

A method of manufacturing a semiconductor structure having a wafer through-contact and a corresponding semiconductor structure

This invention relates to a method of manufacturing a semiconductor structure having a wafer through-contact and a corresponding semiconductor structure.

Through-contacts in silicon wafers, i.e. contacts which interconnect the wafer back- and frontside, are usually provided by forming vias on the wafer frontside in aluminium pads and by subsequent galvanic or currentless deposition (electroplating or electroless plating) of metals (Cu, Ni, Sn, . . . ) or metal alloys (SnPb, SnAg, . . . ) for filling said vias. These vias are usually provided by wet-chemical etching (f.e. KOH) or by dry-chemical etching. The sidewalls of the vias are passivated before filling (f. e. by means of oxide) and coated with a thin metal layer (sputtering, MOCVD, . . . ). The galvanic or currentless processes are relatively complicated and expensive because a relatively large volume in the contact hole has to be filled. Therefore the depth of the hole has to be kept relatively small (typically <50 μm depth).

After having provided the via or vias, the backside of the wafer is polished, and the filled vias are exposed from the backside.

Disadvantages of this process are that the frontside aluminium pads are destroyed or modified. This complicates the WLP process wafer level packaging. The through-silicon vias have a relatively large space requirement in order to provide the desired aspect ratio of the vias. This space must be reserved in the layout (no structures are allowed below the aluminium pads). This is a massive modification of existing memory chip layouts.

After the thinning of the wafer from the backside, the subsequent processes have to be performed with very thin wafers (typically <50 μm thickness) which leads to handling problems. Alternatively, carrier wafers can be used. However, carrier wafer processes are complicated and may restrict subsequent process steps.

The manufacture of the through-silicon vias is performed in the vicinity of active layers. Thus, damages or influences on the functioning of the chips, f.e. memory chips, may be caused.

Accordingly, it is an object of the present invention to provide an improved method of manufacturing a semiconductor structure having a wafer through-contact and a corresponding semiconductor structure which may be easily and safely realized.

According to the present invention, this object is achieved by the manufacturing method of claim 1 and the corresponding semiconductor structure of claim 7, respectively.

The general idea underlying the present invention is to use a known trench process for forming a first part of the through-contact to the chip backside, namely contact trenches which extend from an upper surface of the active wafer region into the bulk wafer region. The method according to the invention uses a fine structuring process on the wafer frontside for providing said contact trenches of typically 15 to 30 μm.

In a second process step, the deep trenches are contacted from the wafer backside by providing a large via, for example by using a KOH wet etch process, and thereafter filling said large via. A coarse structuring technique for forming said aligned via where no semiconductor chip structures are present and only the silicon material has to be removed in a rational way.

The group of deep contact trenches is preferably located below aluminium pads. Preferably, a group of deep trenches is connected to at least one aluminium pad and covers at least a part of the area of the aluminium pad.

The present invention has the major advantage that the through-contacts may be formed by using known frontend processes. Only if few changes in comparison to known chip layouts, f.e. memory chip layouts, are necessary. The wafer may be subjected to the same testing procedures as before. The aluminium pads are neither damaged nor modified. Since only the deep trenches are contacted, a relatively big distance between the through-contacts and the active electronics may be kept. Thus, the risk of damage is minimized.

The etching of vias from the wafer backside may be achieved by dry etching, wet etching, laser drilling or other suited process steps. For the filling of the vias after the passivation of the side walls and the exposure of the trench conductive filling plugs, a sputter and a plating process (electroplating or electro-less plating) may be used. Other processes, for example, filling with solder adhesive could be also suited. If the aspect ratio (widths/depths) of the via is large enough, a metalization may also be realized by sputtering/plating in order to achieve the electrical contact to the backside.

In the dependent claims, preferred embodiments of the subject matter of claims 1 and 7, respectively, are listed.

According to a preferred embodiment the first conductive filling in said plurality of contact trenches is connected on the upper surface such that it short-circuits all of said plurality of contact trenches.

According to another preferred embodiment an on-wafer region is formed on the upper surface which on-wafer region includes a third dielectric isolation layer above said plurality of contact trenches, and wherein one or more conductive contact plugs are formed in said third dielectric isolation layer such that they contact said filling in said plurality of contact trenches.

According to another preferred embodiment said active has a depth of about 5 to 10 micrometer and said plurality of contact trenches has a depth of about 15 to 30 micrometer, and said wafer has a thickness of about 100 to 800 micrometer.

According to another preferred embodiment the exposing of said conductive filling of said plurality of contact trenches is detected optically.

According to another preferred embodiment the exposing of said conductive filling of said plurality of contact trenches is detected chemically.

The embodiments of the present invention are illustrated in the drawings and will be explained in detail in the following description.

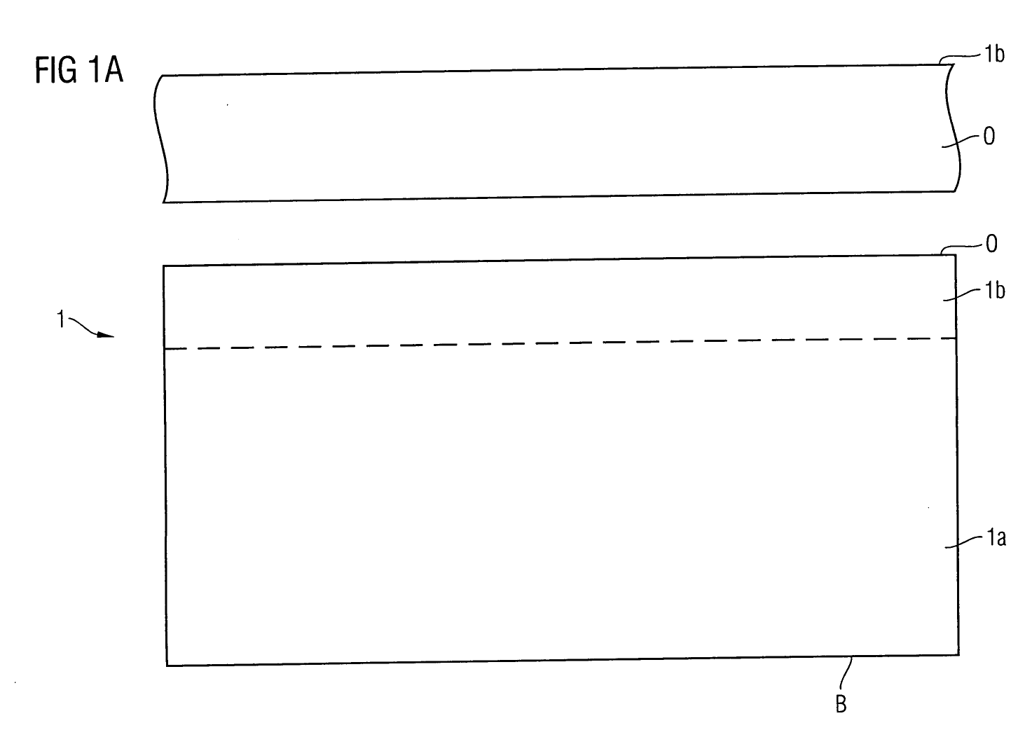

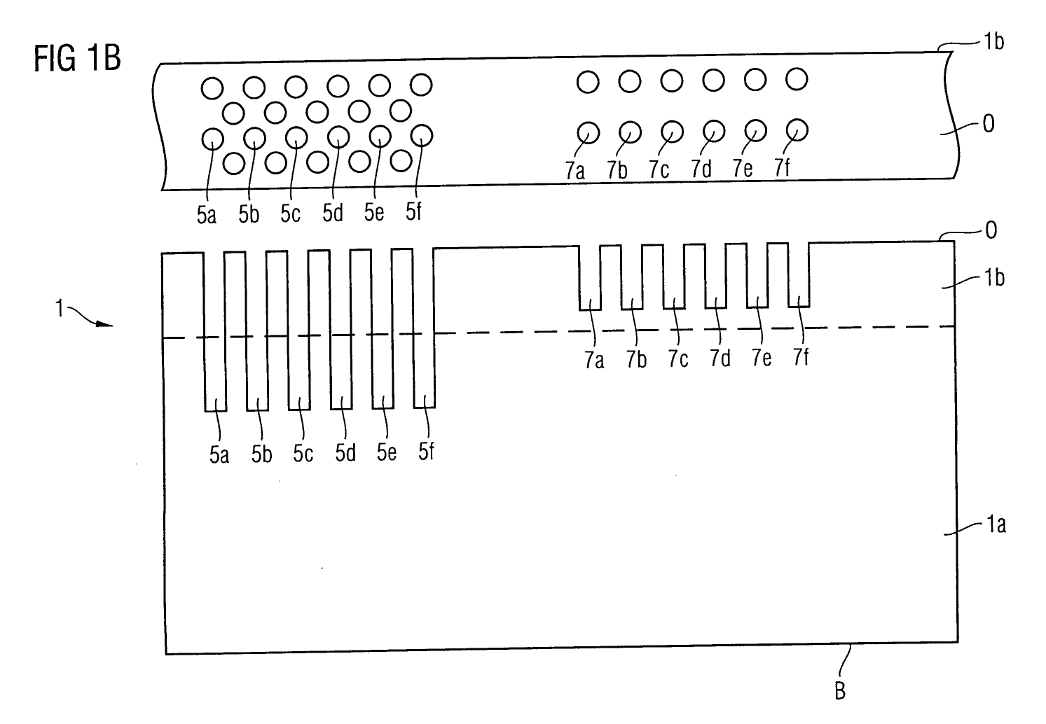

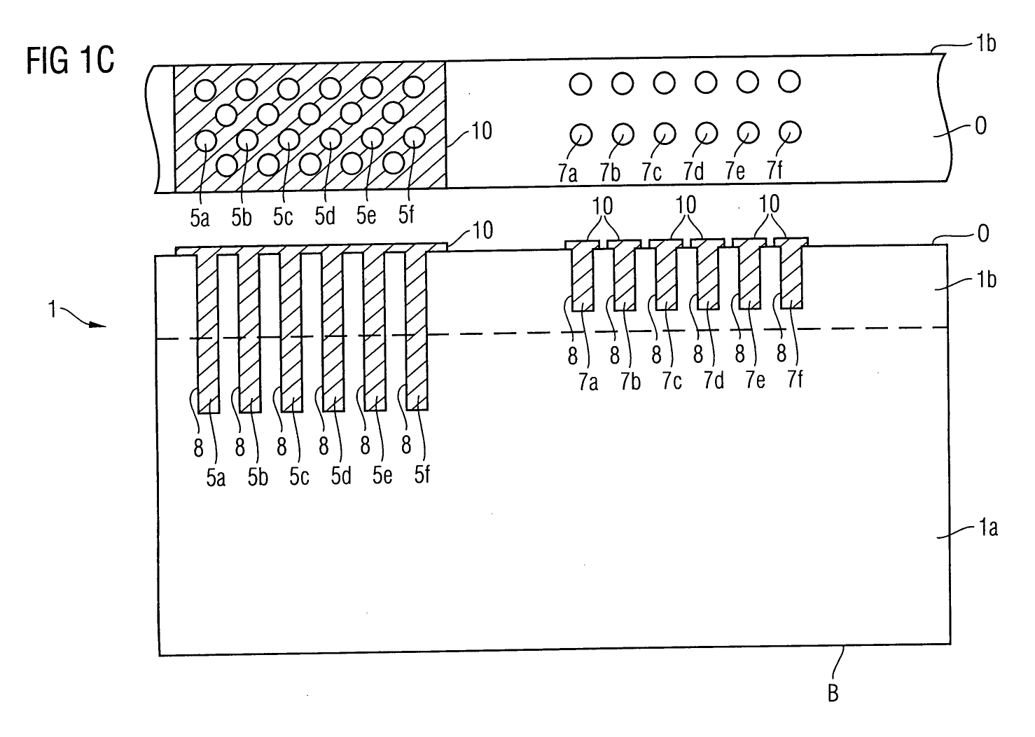

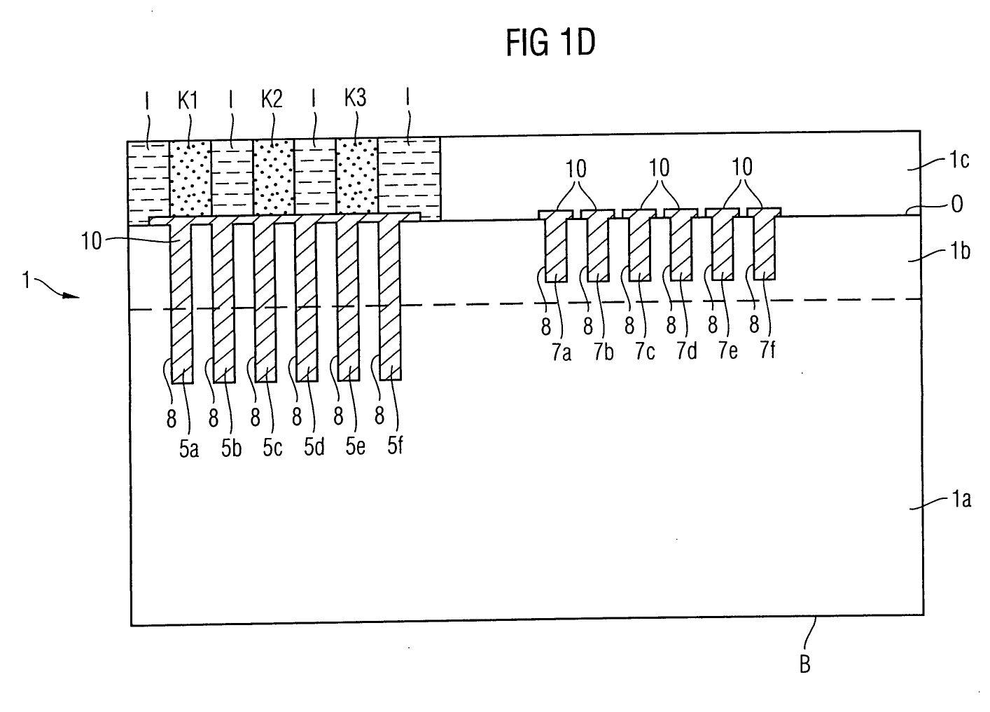

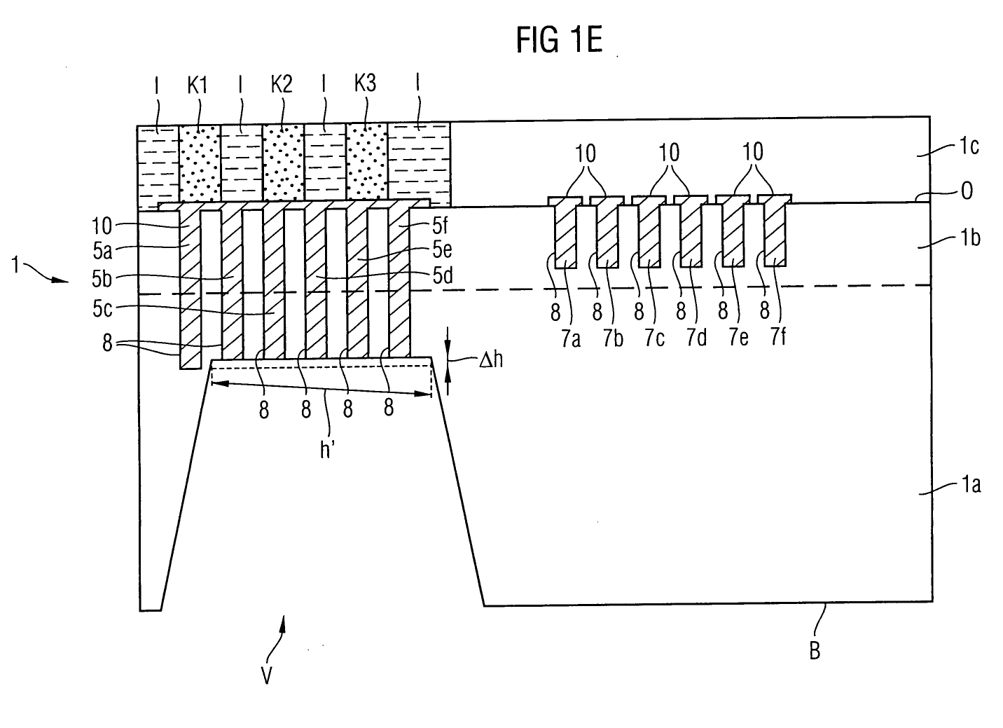

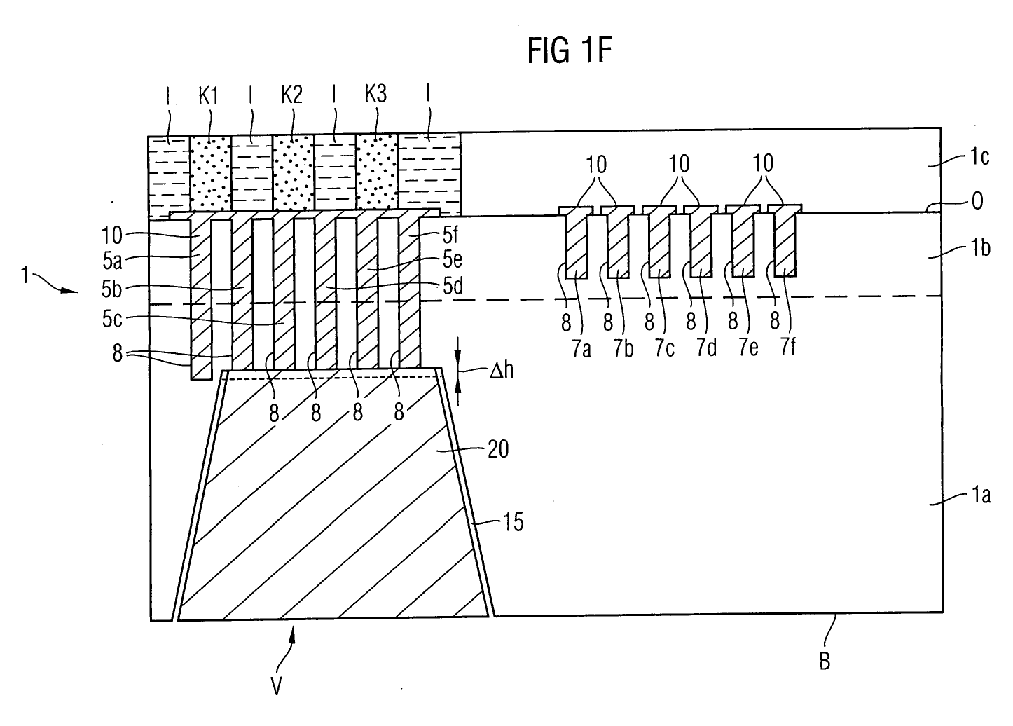

FIGS. 1A to 1F show schematic illustrations of subsequent process steps of a manufacturing method for a semiconductor structure having a wafer through-contact and a corresponding semiconductor structure as embodiment of the present invention.

In the figures, the same reference signs denote identical or functionally equivalent parts.

In FIG. 1A, reference sign 1 denotes a silicon semiconductor wafer. A typical thickness of the silicon semiconductor wafer A is between 100 and 760 μm. The silicon semiconductor wafer 1 comprises a bulk region 1a on the wafer backside B and an active region 1b where integrated circuit elements such as memory cells and peripheral devices will be formed on the wafer frontside O. In the upper part of FIG. 1A, a partial view onto the upper surface O of the active region 1b is shown.

In the next process step, which is illustrated in FIG. 1B, memory capacitor trenches 7a-7f are formed in the active region 1b, and a plurality of contact trenches 5a-5f is formed in the active region 1b which contact trenches 5a-5f reach into the bulk region 1a. Typical depths of the memory capacitor trenches 7a-7f are 5 to 10 μm and typical depths of the contact trenches 5a-5f are 15 to 30 μm. These trenches 5a-5f and 7a-7f may be formed in two subsequent process steps using a well-known anisotropic trench plasma etch process and using corresponding hard-masks in order to define the location of the trenches 5a-5f and 7a-7f, respectively.

In the upper part of FIG. 1B the partial view onto the upper surface O is shown which reveals that both, the memory capacitor trenches 7a-7f and the contact trenches 5a-5f are arranged in respective two-dimensional arrays.

Next, as shown in FIG. 1C, a dielectric layer 8 is formed in the trenches 5a-5f and 7a-7f and on the upper surface O of the active region. Then, (not shown) TiN plating is provided on the dielectric layer 8, and finally a conductive polysilicon layer 10 is deposited over the structure which conductive polysilicon layer 10 completely fills the trenches 5a-5f and 7a-7f, respectively. In a subsequent process step, the conductive polysilicon layer 10 is structured on the upper surface O in such a way, that it commonly connects all of the contact trenches 5a-5f, whereas it separately contacts each memory capacitor trenches 7a-7f individually, because one memory capacitor trench belongs to one memory cell.

In a next process step, which is schematically shown in FIG. 1D, semiconductor memory cells comprising memory trench capacitors 7a-7f and (not shown) selection transistors as well as other circuit elements are formed on the surface O of the active region 1b in a on-wafer region 1c. In the on-wafer region 1c above and around the contact trenches 5a-5f an isolation layer I is deposited, for example, a silicon oxide layer, and Tungsten contact plugs K1, K2, K3 are formed in said isolation layer I which contact plugs K1, K2, K3 contact the conductive poly-silicon layer 10 that short circuits the polysilicon fillings 10 of the contact trenches 5a-5f.

In a next process, step which is shown in FIG. 1E, a backside via V is provided from the backside B of the bulk region 1a of the silicon semiconductor wafer 1. This backside via is formed by a wet etch process using KOH, for example. The position of the backside via V has to be adjusted by a usually front side/backside alignment procedure, the accuracy of which is 1 to 2 μm for optical systems and 3 to 5 μm for infrared systems. When etching the backside via V, the contact trenches 5b-5f are opened on their bottom side and the part corresponding to a depth of Δh is removed in order to make sure that the poly-silicon filling 10 is exposed to the backside B.

Also shown in FIG. 1E is, that slight alignment errors—here shown regarding contact trench 5a—are not critical because the widths W of the backside via V is designed such that it covers a plurality of contact trenches 5b-5f in two dimensions and the contact trenches are short-circuited.

Also uncritical is the depth of the backside via V as long as about 5 μm in depth of the contact trenches 5a-5f are left. Actually, the known wet etch process allows an accuracy of 2 to 3 μm in connection witch etch rates of about 3 to 6 μm/minute. An etchstop may be provided either chemically or optically.

In a final process step, which is shown in FIG. 1F, a passivation layer 15 is formed on the sidewalls of the backside via V, and a conductive fill 20, for example, a metal fill of Tungsten is provided in the backside via V which conductive fill 20 contacts the conductive poly-silicon filling 10 of the contact trenches 5b-5f.

Now, a conductive through-contact or interconnect reaching from the upper side of the on-wafer layer 1c through the contact plugs K1, K2, K3, and the conductive polysilicon filling 10 and the conductive metal filling 20 to the backside of the bulk region 1a of the silicon semiconductor wafer 1 has been established.

It should be further mentioned that it is possible to form a multi-stacked package with such wafer interconnects by simply stacking a plurality wafers as shown in FIG. 1F on top of each other. Thereafter, these stacked wafers may be separated to individual chips stacks.

Although the present invention has been explained with respect to a specific embodiment, it is not limited thereto, but may be modified in various ways.

Particularly, the use of the through-contact for semiconductor memory circuits is only an example, and many other uses in the microelectronics field may be conceived.

Moreover, it is also possible to omit the on-wafer layer 1c and to have only the through-contact reaching from the upper surface of the active region to the back surface of the bulk region.

1. A method of manufacturing a semiconductor structure having a wafer through-contact comprising the steps of:
(a) providing a semiconductor wafer having a bulk region and an active region;
(b) forming a plurality of contact trenches in said semiconductor wafer which extend from an upper surface of said active region into said bulk region;
(c) forming a first dielectric isolation layer on the sidewalls and the bottoms of said contact trenches;
(d) providing a first conductive filling in said plurality of contact trenches;
(e) forming an aligned via in said semiconductor wafer which extends from a backside of said bulk region into said plurality of contact trenches and exposes the conductive filling of said plurality of contact trenches;
(f) providing a second dielectric isolation layer on the sidewall of said via; and
(g) providing a second conductive filling in said via which contacts the exposed conductive filling of said plurality of contact trenches thus forming said wafer through-contact.

2. The method of claim 1, wherein the first conductive filling in said plurality of contact trenches is connected on the upper surface such that it short-circuits all of said plurality of contact trenches.

3. The method of claim 2, wherein an on-wafer region is formed on the upper surface which on-wafer region includes a third dielectric isolation layer above said plurality of contact trenches, and wherein one or more conductive contact plugs are formed in said third dielectric isolation layer such that they contact said filling in said plurality of contact trenches.

4. The method of claim 1, wherein said active has a depth of about 5 to 10 micrometer and said plurality of contact trenches has a depth of about 15 to 30 micrometer, and said wafer has a thickness of about 100 to 800 micrometer.

5. The method of claim 1, wherein the exposing of said conductive filling of said plurality of contact trenches is detected optically.

6. The method of claim 1, wherein the exposing of said conductive filling of said plurality of contact trenches is detected chemically.

7. A semiconductor structure having a wafer through-contact comprising:
(a) a semiconductor wafer having a bulk region and an active region;
(b) a plurality of contact trenches in said semiconductor wafer which extend from an upper surface of said active region into said bulk region;
(c) a first dielectric isolation layer on the sidewalls and the bottoms of said contact trenches;
(d) a first conductive filling in said plurality of contact trenches;
(e) an aligned via in said semiconductor wafer which extends from a backside of said bulk region into said plurality of contact trenches and exposes the conductive filling of said plurality of contact trenches;
(f) a second dielectric isolation layer on the sidewall of said via; and
(g) a second conductive filling in said via which contacts the exposed conductive filling of said plurality of contact trenches thus forming said wafer through-contact.

8. The structure of claim 7, wherein the first conductive filling in said plurality of contact trenches is connected on the upper surface such that it short-circuits all of said plurality of contact trenches.

9. The structure of claim 8, wherein an on-wafer region is formed on the upper surface which on-wafer region includes a third dielectric isolation layer above said plurality of contact trenches and wherein one or more conductive contact plugs are formed in said third dielectric isolation layer such that they contact said filling in said plurality of contact trenches.

10. The structure of claim 7, wherein said active has a depth of about 5 to 10 micrometer and said plurality of contact trenches has a depth of about 15 to 30 micrometer, and said wafer has a thickness of about 100 to 800 micrometer.
